(19) United States
(12) Patent Application Publication
(10) Pub. No.: US 2026/0196263 A1
(43) Pub. Date: Jul. 9, 2026

(54) SENSE AMPLIFIER AND MEMORY DEVICE INCLUDING THE SAME

(71) Applicant: SAMSUNG ELECTRONICS CO, LTD., Suwon-si (KR)

(72) Inventors: Hyunjun KIM, Suwon-si (KR); Seong-ook JUNG, Seoul (KR); Wonhyeok HONG, Seoul (KR); Giseok KIM, Seoul (KR)

(73) Assignees: SAMSUNG ELECTRONICS CO, LTD., Suwon-si (KR); UIF (UNIVERSITY INDUSTRY FOUNDATION) YONSEI UNIVERSITY, Seoul (KR)

(21) Appl. No.: 19/438,172

(22) Filed: Dec. 31, 2025

(30) Foreign Application Priority Data
Jan. 9, 2025 (KR) 10-2025-0003365

(51) Int. Cl. G11C 11/419; G11C 5/14; G11C 11/418

(52) U.S. Cl. CPC G11C 11/419; G11C 5/146; G11C 11/418

(57) ABSTRACT

The sense amplifier includes a first PMOS transistor and a first NMOS transistor connected in series between a power supply voltage and an input node, a second NMOS transistor connected between the input node and a ground, a second PMOS transistor, a third NMOS transistor, and a fourth NMOS transistor connected in series between the power supply voltage and the ground, a first switch connected between a first node between the first PMOS transistor and the first NMOS transistor and a second node between the second PMOS transistor and the third NMOS transistor, and a second switch connected between the second node and an output node.

### CROSS-REFERENCE TO RELATED APPLICATIONS

This application is based on and claims priority under 35 U.S.C. § 119 to Korean Patent Application No. 10-2025-0003365 filed on January 9, 2025, in the Korean Intellectual Property Office, the disclosures of which are incorporated by reference herein in their entireties.

### BACKGROUND

Embodiments of the present disclosure described herein relate to a sense amplifier and a memory device including the sense amplifier.

A memory device using a semiconductor is classified as a volatile memory device or a nonvolatile memory device. The volatile memory device refers to a type of memory device, in which, data stored in the memory device is lost when a power is turned off. The volatile memory device may include, but is not limited to, a static random access memory (SRAM), a dynamic random access memory (DRAM), a synchronous dynamic random access memory (SDRAM), etc.

The SRAM may include a 6T SRAM cell implemented by using six transistors or an 8T SRAM cell implemented by using eight transistors. Compared to the 6T SRAM cell, the 8T SRAM cell may further include two additional transistors constituting a read port for performing a read operation. Accordingly, since the 8T SRAM cell separately includes the read port, the read operation and the write operation on the 8T SRAM cell may be simultaneously performed.

Also, a bit line which is connected to at least some of transistors constituting a memory cell of the SRAM may be connected to a sense amplifier. The sense amplifier may read data stored in the memory cell based on a current flowing through the bit line.

### SUMMARY

One or more embodiments of the present disclosure provide a sense amplifier capable of improving a speed and power efficiency of a read operation on a memory cell.

According to an aspect of the disclosure, there is provided a sense amplifier including: a first p-channel metal–oxide–semiconductor (PMOS) transistor and a first n- channel metal–oxide–semiconductor (NMOS) transistor connected in series between a power supply voltage and an input node of the sense amplifier; a second NMOS transistor connected between the input node and a ground; a second PMOS transistor, a third NMOS transistor, and a fourth NMOS transistor connected in series between the power supply voltage and the ground; a first switch connected between a first node between the first PMOS transistor and the first NMOS transistor and a second node between the second PMOS transistor and the third NMOS transistor; and a second switch connected between the second node and an output node of the sense amplifier, wherein a gate electrode of the first PMOS transistor is connected to the ground, wherein a gate electrode of the first NMOS transistor is connected to the power supply voltage, wherein a gate electrode of the second NMOS transistor is connected to the input node, and wherein a gate electrode of the second PMOS transistor is connected to the first node.

According to another aspect of the disclosure, there is provided a memory device including: a memory cell array including a plurality of memory cells connected to a first read bit line; and a sense amplifier connected to the first read bit line, wherein the sense amplifier includes: a first p-channel metal–oxide–semiconductor (PMOS) transistor, a first n-channel metal–oxide–semiconductor (NMOS) transistor, and a second NMOS transistor connected in series between a power supply voltage and a ground; a second PMOS transistor, a third NMOS transistor, and a fourth NMOS transistor connected in series between the power supply voltage and the ground; and a first switch connected between a first node between the first PMOS transistor and the first NMOS transistor and a second node between the second PMOS transistor and the third NMOS transistor, wherein a gate electrode of the first PMOS transistor is connected to the ground, wherein a gate electrode of the first NMOS transistor is connected to the power supply voltage, and wherein a gate electrode of the second PMOS transistor is connected to the first node.

According to another aspect of the disclosure, there is provided a sense amplifier which is connected to a plurality of memory cells, including: a first p-channel metal–oxide–semiconductor (PMOS) transistor, a first n-channel metal–oxide–semiconductor (NMOS) transistor, and a second NMOS transistor connected in series between a power supply voltage and a ground; a first switch connected between a first node between the first PMOS transistor and the first NMOS transistor and a second node; a second PMOS transistor connected between the power supply voltage and the second node; and a second switch connected between the second node and an output node, wherein the first switch is turned on based on a reset signal, and wherein, while the first switch is turned on, the first node and the second node are connected and a voltage of the first node changes from the power supply voltage to a first voltage based on a characteristic of the second PMOS transistor.

### BRIEF DESCRIPTION OF DRAWINGS

The above and other objects and features of the present disclosure will become apparent by describing in detail embodiments thereof with reference to the accompanying drawings.

FIG. 1 is a block diagram of a memory device according to an embodiment of the present disclosure.

FIG. 2 is a circuit diagram of a first memory cell according to an embodiment.

FIG. 3A is a circuit diagram of a first sense amplifier in a precharge operation according to an embodiment.

FIG. 3B is a circuit diagram of a first sense amplifier in a read operation on a first memory cell according to an embodiment.

FIG. 4 illustrates signals for an operation of reading data stored in a first memory cell through a first sense amplifier according to an embodiment.

FIG. 5 is a circuit diagram of a first sense amplifier according to another embodiment.

FIG. 6A illustrates voltages of respective nodes included in a first sense amplifier in an operation where data “1” stored in a first memory cell are read, according to an embodiment.

FIG. 6B illustrates voltages of respective nodes included in a first sense amplifier in an operation where data “0” stored in a first memory cell are read, according to another embodiment.

FIG. 7 illustrates a cumulative probability distribution function of an access time using a first sense amplifier according to an embodiment and a cumulative probability distribution function of an access time using a sense amplifier not including a first switch and a second switch.

FIG. 8 is a block diagram illustrating an example of a hardware structure of a mobile device including a memory device according to an embodiment of the present disclosure.

### DETAILED DESCRIPTION

Below, embodiments of the present disclosure will be described in detail and clearly to such an extent that one skilled in the art easily carries out the present disclosure.

In the present disclosure, the expressions “first”, “second”, etc. may modify various components regardless of the order and/or the importance, are only used to distinguish one component from another component, and are not intended to limit the order or importance of components.

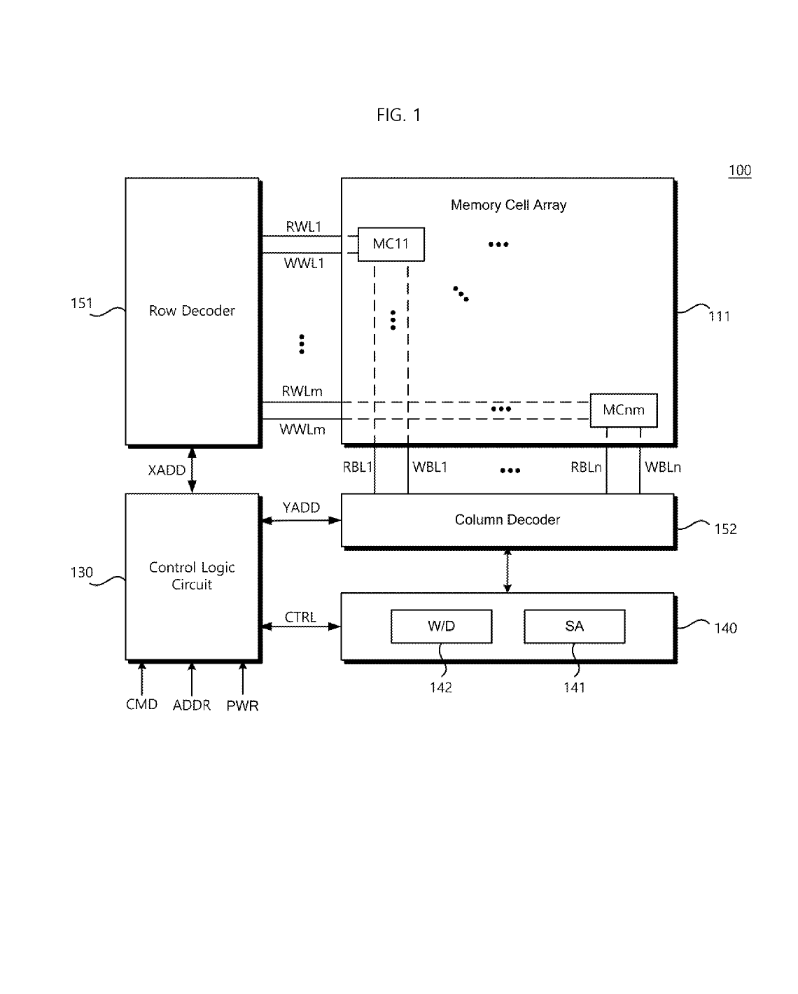

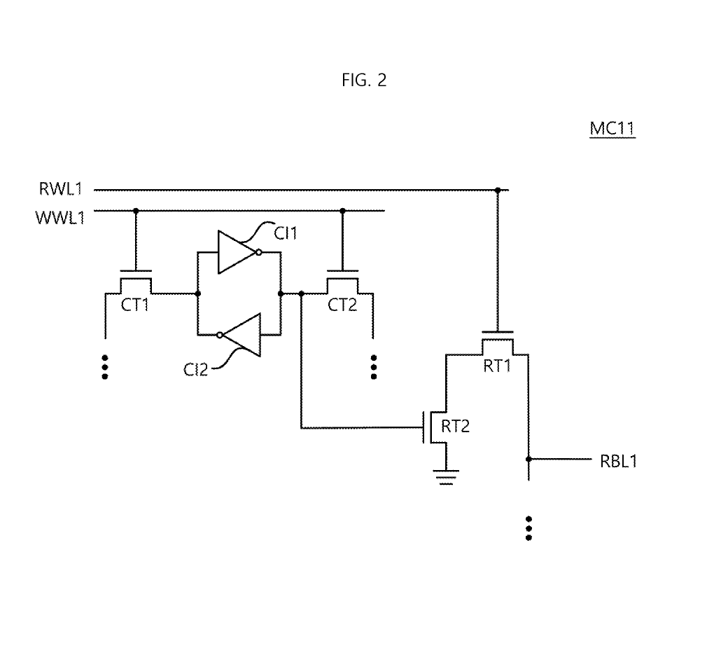

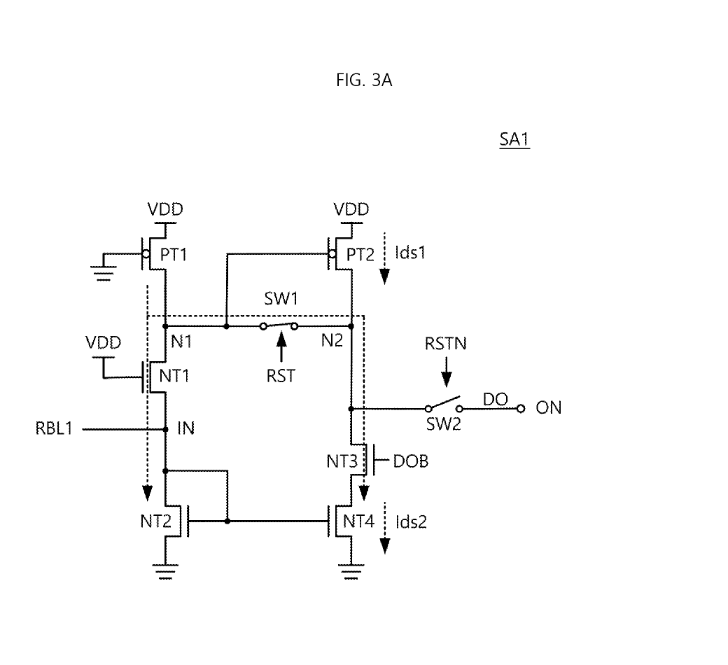

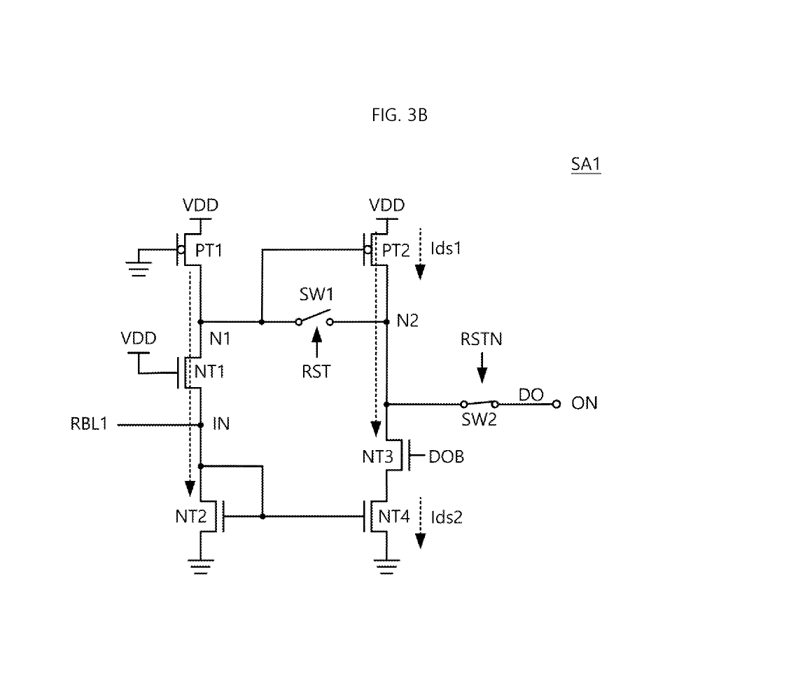

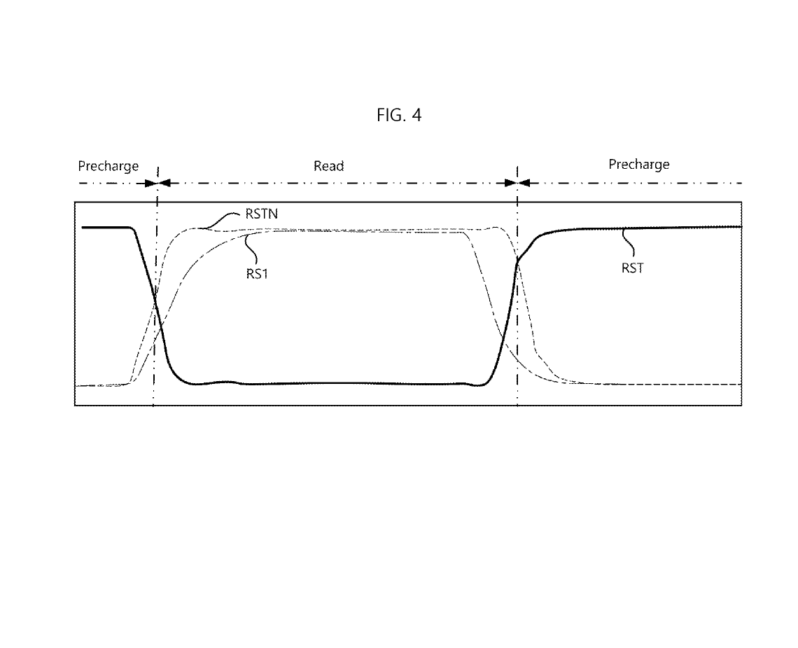

FIG. 1 is a block diagram of a memory device according to an embodiment of the present disclosure. FIG. 2 is a circuit diagram of a first memory cell according to an embodiment. FIG. 3A is a circuit diagram of a first sense amplifier in a precharge operation according to an embodiment. FIG. 3B is a circuit diagram of a first sense amplifier in a read operation on a first memory cell according to an embodiment. FIG. 4 illustrates signals for an operation of reading data stored in a first memory cell through a first sense amplifier according to an embodiment.

Referring to FIG. 1, a memory device 100 according to an embodiment may include a memory cell array 111, a control logic circuit 130, a row decoder 151, a column decoder 152, and an input/output driver 140. However, the disclosure is not limited thereto, and as such, according to an embodiment, the memory device 100 may include one or more other components.

The memory cell array 111 according to an embodiment may include a plurality of memory cells MC11 to MCnm arranged in a matrix form with rows and columns. Herein, the plurality of memory cells MC11 to MCnm may be connected to a plurality of read word lines RWL1 to RWLm, a plurality of write word lines WWL1 to WWLm, a plurality of read bit lines RBL1 to RBLn, and a plurality of write bit lines WBL1 to WBLn.

For example, the first memory cell MC11 may be connected to the first read word line RWL1, the first write word line WWL1, the first read bit line RBL1, and the first write bit line WBL1.

According to an embodiment, each of the plurality of memory cells MC11 to MCnm may be implemented with a nonvolatile memory cell. For example, each of the plurality of memory cells MC11 to MCnm may be implemented with a static random access memory (SRAM) cell. However, the disclosure is not limited thereto, and as such, according to an embodiment, the plurality of memory cells may be implanted according to another type of memory cell.

Referring to FIG. 2, the first memory cell MC11 according to an embodiment may be implemented with an SRAM cell including a plurality of transistors.

The first memory cell MC11 may include a first cell transistor CT1, a second cell transistor CT2, a first cell inverter CI1, a second cell inverter CI2, a first read transistor RT1, and a second read transistor RT2.

According to an embodiment, the first memory cell MC11 may include the first cell transistor CT1 and the second cell transistor CT2, each of which is connected to the first write word line WWL1. Herein, the first cell transistor CT1 and the second cell transistor CT2 may be turned on or turned off by a signal which is applied to the gate electrodes of the respective transistor through the first write word line WWL1. For example, the first cell transistor CT1 may be controlled to be turned on or turned off based on a signal (e.g., the first write word line WWL1 signal) applied to a gate electrode of the first cell transistor CT1 and the second cell transistor CT2 may be controlled to be turned on or turned off based on a signal (e.g., the first write word line WWL1 signal) applied to a gate electrode of the second cell transistor CT2.

According to an embodiment, the first memory cell MC11 may include the first read transistor RT1, and the first read transistor RT1 may be connected to the first read bit line RBL1. For example, the first read transistor RT1 may receive a signal applied from the first read word line RWL1 through the gate electrode of the first read transistor RT1. That is, for example, in the read operation on the first memory cell MC11, the first read transistor RT1 may be turned on by the signal applied through the first read word line RWL1.

According to an embodiment, the first memory cell MC11 may include the second read transistor RT2, and the second read transistor RT2 may be connected to a ground. The second read transistor RT2 may receive a voltage of one node between the first cell transistor CT1 and the second cell transistor CT2 through the gate electrode the second read transistor RT2. Herein the voltage of the one node between the first cell transistor CT1 and the second cell transistor CT2 may be referenced as data previously stored in the first memory cell MC11.

Accordingly, in the read operation on the first memory cell MC11, depending on the data previously stored in the first memory cell MC11, the first read bit line RBL1 may be connected to the ground or may be electrically open.

Referring to the above components, the first memory cell MC11 according to an embodiment of the present disclosure may be referenced as a multi-port SRAM cell in which an electrical path for the read operation and an electrical path for the write operation are distinguished from each other.

According to an embodiment, the first memory cell MC11 may include the first cell inverter CI1 and the second cell inverter CI2, and the first cell inverter CI1 and the second cell inverter CI2 may be connected between the first cell transistor CT1 and the second cell transistor CT2.

According to an embodiment, the first memory cell MC11 may include the first cell inverter CI1 and the second cell inverter CI2 which are connected in parallel between the first cell transistor CT1 and the second cell transistor CT2.

The first memory cell MC11 may include the first cell inverter CI1 which inverts a signal output from the first cell transistor CT1. Also, the first memory cell MC11 may include the second cell inverter CI2 which inverts a signal output from the second cell transistor CT2.

Herein, each of the first cell inverter CI1 and the second cell inverter CI2 may be implemented with two transistors which are connected between a power supply voltage and the ground. Also, the plurality of memory cells MC11 to MCnm may include substantially the same configuration. Accordingly, each of the plurality of memory cells MC11 to MCnm according to an embodiment of the present disclosure may be referred to as an 8T SRAM cell.

Referring to FIG. 1, the memory device 100 may include the control logic circuit 130 which stores data in at least some of the plurality of memory cells MC11 to MCnm or reads data stored in each of the plurality of memory cells MC11 to MCnm. For example, the control logic circuit 130 may control at least some of the plurality of memory cells MC11 to MCnm to store data or read data stored in each of at least some of the plurality of memory cells MC11 to MCnm. For example, the control logic circuit 130 may output (or be configured to output) control signals to write data to one or more of the plurality of memory cells MC11 to MCnm or read data from one or more of the plurality of memory cells MC11 to MCnm. The control signals may include, but is not limited to, a read signal or a write signal.

The control logic circuit 130 may execute, for example, software (e.g., a program) to control at least another component (e.g., the memory cell array 111) of the memory device 100 and to perform various data processing or calculations (or computations). The control logic circuit 130 may include a central processing unit, a microprocessor, etc. and may control all the operations of the memory device 100. Accordingly, the operation which is performed by the memory device 100 may be understood as being performed under control of the control logic circuit 130.

The control logic circuit 130 according to an embodiment may control the read operation and/or the write operation of the memory device 100 by using commands CMD, addresses ADDR, and an external power PWR provided from the outside.

Herein, the addresses ADDR may include a row address XADD for selecting one memory cell or one word line and a column address YADD for selecting one memory cell.

Accordingly, for example, based on a read command among the commands CMD, the control logic circuit 130 may read data stored in at least one memory cell (e.g., the first memory cell MC11) specified by the addresses ADDR from among the plurality of memory cells MC11 to MCnm. For example, in response to a read command among the commands CMD, the control logic circuit 130 may read data stored in at least one memory cell (e.g., the first memory cell MC11) specified by the addresses ADDR from among the plurality of memory cells MC11 to MCnm.

According to an embodiment, the memory device 100 may include the row decoder 151 and the row decoder 151 may select a read word line among the plurality of read word lines RWL1 to RWLm and a write word line among the plurality of write word lines WWL1 to WWLm, and the selected read word line and the selected write word line may correspond to each other.

According to an embodiment, the row decoder 151 may decode the row address XADD to activate a word line corresponding to the row address XADD from among the plurality of read word lines RWL1 to RWLm and the plurality of write word lines WWL1 to WWLm.

For example, the row decoder 151 may decode the row address XADD to activate the first read word line RWL1 for the read operation on the first memory cell MC11.

Herein, for example, the row decoder 151 may further include a plurality of word line drivers which are respectively connected to the plurality of read word lines RWL1 to RWLm and are respectively connected to the plurality of write word lines WWL1 to WWLm. However, for another example, the plurality of word line drivers may be implemented as a component independent of the row decoder 151 and may be connected to the row decoder 151.

According to an embodiment, the memory device 100 may include the column decoder 152 which selects at least some of the plurality of read bit lines RBL1 to RBLn and the plurality of write bit lines WBL1 to WBLn.

According to an embodiment, the column decoder 152 may decode the column address YADD to activate at least some of the plurality of read bit lines RBL1 to RBLn and the plurality of write bit lines WBL1 to WBLn.

For example, the column decoder 152 may decode the column address YADD to activate the first read bit line RBL1 for the read operation on the first memory cell MC11.

According to an embodiment, the memory device 100 may include the input/output (IO) driver 140 which stores data in the memory cell array 111 or reads data from the memory cell array 111, based on a control signal CTRL.

During the program (or write) operation, the input/output driver 140 may be provided with program data from outside of the memory device 100. For example, the input/output driver 140 may be provided with program data from a device or component that is external to the memory device 100. Also, during the read operation, the input/output driver 140 may provide the data read from the memory cell array 111 to the outside of the memory device 100. For example, the input/output driver 140 may provide the data read from the memory cell array 111 to a device or a component that is external to the memory device 100.

The input/output driver 140 according to an embodiment may include a sense amplifier (SA) circuit 141 and a write driver (W/D) 142.

According to an embodiment, the sense amplifier circuit 141 may sense a current flowing through a read bit line (e.g., the first read bit line RBL1) in the read operation.

According to an embodiment, as a signal is applied to a selected memory cell through the read word line, the sense amplifier circuit 141 may sense a current flowing through the read bit line. Herein, the magnitude of the current flowing through the read bit line may be determined based on (or depending on) the data stored in the selected memory cell.

According to the above description, the sense amplifier circuit 141 may read the data stored in the selected memory cell.

Herein, the sense amplifier circuit 141 may include a plurality of sense amplifiers respectively corresponding to the plurality of read bit lines RBL1 to RBLn. For example, referring to FIGS. 3A and 3B together, the sense amplifier circuit 141 may include a first sense amplifier SA1 which is connected to the first read bit line RBL1.

According to an embodiment, the write driver 142 may receive the control signal CTRL and may provide a write current to the column decoder 152.

Referring to FIGS. 3A and 3B, the first sense amplifier SA1 according to an embodiment may include a plurality of transistors PT1, PT2, NT1, NT2, NT3, and NT4, a first switch SW1, and a second switch SW2. Herein, the first sense amplifier SA1 may be connected to the first read bit line RBL1 through an input node IN. For example, the plurality of transistors may include a first p-channel metal–oxide–semiconductor (PMOS) transistor PT1, a second PMOS transitor PT2, a first n-channel metal–oxide–semiconductor (NMOS) transistor NT1, a second NMOS transistor NT2, a third NMOS transistor NT3, and a fourth NMOS transistor NT4.

The first sense amplifier SA1 may include the first PMOS transistor PT1 and the first NMOS transistor NT1 connected in series between a power supply voltage VDD and the input node IN.

Herein, the gate electrode of the first PMOS transistor PT1 may be connected to the ground. Also, the gate electrode of the first NMOS transistor NT1 may be connected to the power supply voltage VDD. That is, each of the first PMOS transistor PT1 and the first NMOS transistor NT1 may maintain a turn-on state.

Also, the first sense amplifier SA1 may include the second NMOS transistor NT2 connected between the input node IN and the ground. Herein, the gate electrode of the second NMOS transistor NT2 may be connected to the input node IN.

Also, the first sense amplifier SA1 may include the second PMOS transistor PT2, the third NMOS transistor NT3, and the fourth NMOS transistor NT4 connected in series between the power supply voltage VDD and the ground.

Herein, the gate electrode of the second PMOS transistor PT2 may be connected to a first node N1. Also, the third NMOS transistor NT3 may receive an inverse output signal DOB through the gate electrode the third NMOS transistor NT3. For example, the inverse output signal DOB is an inverted version of an output signal DO. Also, the gate electrode of the fourth NMOS transistor NT4 may be connected to the input node IN.

In addition, the first sense amplifier SA1 may include the first switch SW1 connected between the first node N1 between the first PMOS transistor PT1 and the first NMOS transistor NT1 and a second node N2 between the second PMOS transistor PT2 and the third NMOS transistor NT3.

Furthermore, the first sense amplifier SA1 may include the second switch SW2 connected between the second node N2 and an output node ON.

Referring to FIGS. 1, 3A, 3B, and 4 together, the control logic circuit 130 according to an embodiment may control the first switch SW1 by using a reset signal RST. Also, the control logic circuit 130 may control the second switch SW2 by using an inverse reset signal RSTN, which is an inverted version of the reset signal RST.

For example, the control logic circuit 130 may turn off the second switch SW2 while turning on the first switch SW1 and may turn on the second switch SW2 while turning off the first switch SW1.

Referring to FIGS. 3A and 4, in the precharge operation on the first memory cell MC11, the control logic circuit 130 according to an embodiment may turn on the first switch SW1 by applying the reset signal RST of a logic high level to the first switch SW1. In this case, the first node N1 and the second node N2 may be electrically connected.

According to an embodiment, when the first node N1 and the second node N2 are connected, the voltage level of the first node N1 may decrease as much as a bias value which is determined depending on a characteristic of each of the second PMOS transistor PT2 and the fourth NMOS transistor NT4.

According to an embodiment, while the first switch SW1 is turned on, the voltage level of the first node N1 may decrease from the power supply voltage VDD as much as the bias value, which is determined depending on the characteristic of each of the second PMOS transistor PT2 and the fourth NMOS transistor NT4, as the first node N1 and the second node N2 are connected.

Herein, the characteristic of each transistor may be understood as the magnitude of a drain current of each transistor under a specified condition. For example, the characteristic of the second PMOS transistor PT2 may include the magnitude of a first drain current Ids1 of the second PMOS transistor PT2. Also, the characteristic of the fourth NMOS transistor NT4 may include the magnitude of a second drain current Ids2 of the fourth NMOS transistor NT4.

Accordingly, while the first switch SW1 is turned on, the voltage level of the first node N1 may decrease as much as a bias value which is determined depending on a difference between the magnitude of the drain current Ids1 of the second PMOS transistor PT2 and the magnitude of the drain current Ids2 of the fourth NMOS transistor NT4.

Herein, for example, the bias value may be inversely proportional to the magnitude of the first drain current Ids1 and may be proportional to the magnitude of the second drain current Ids2. That is, as the magnitude of the first drain current Ids1 becomes smaller and the magnitude of the second drain current Ids2 becomes greater, the voltage level of the first node N1 may relatively decrease more. In another example, as the magnitude of the first drain current Ids1 becomes greater and the magnitude of the second drain current Ids2 becomes smaller, the voltage level of the first node N1 may relatively decrease less.

That is, during the precharge operation, the voltage level of the first node N1 may decrease from the power supply voltage VDD as much as a value according to a characteristic difference of the second PMOS transistor PT2 and the fourth NMOS transistor NT4.

According to an embodiment, in the precharge operation, the control logic circuit 130 may turn off the second switch SW2 by applying the inverse reset signal RSTN of a logic low level to the second switch SW2. In this case, the second node N2 may be electrically separated from the output node ON.

For example, the control logic circuit 130 may open the second switch SW2 to prevent a voltage change of the first node N1 and the second node N2 during the precharge operation from affecting the output node ON.

According to an embodiment, in the read operation on the first memory cell MC11, the control logic circuit 130 may turn off the first switch SW1 by applying the reset signal RST of the logic low level to the first switch SW1. In this case, the first node N1 and the second node N2 may be electrically separated from each other.

Referring to FIGS. 2, 3B and 4 together, according to an embodiment, in an example case in which a first read signal RS1 is applied to the first memory cell MC11 through the first read word line RWL1, the voltage level of the first node N1 may decrease.

According to an embodiment, assuming that data “1” are previously stored in the first memory cell MC11, the first read transistor RT1 and the second read transistor RT2 of the first memory cell MC11 may be turned on based on the first read signal RS1 applied through the first read word line RWL1. For example, the first read transistor RT1 and the second read transistor RT2 of the first memory cell MC11 may be turned on in response to the first read signal RS1 applied through the first read word line RWL1.

As the first read transistor RT1 and the second read transistor RT2 are turned on, the first node N1 may be connected to the ground through the first read bit line RBL1. That is, in the read operation on the first memory cell MC11, a current may flow from the first node N1 to the ground through the first read bit line RBL1.

Herein, the voltage level of the first node N1 may decrease from the value decreased during the precharge operation to a value enough to turn on the second PMOS transistor PT2.

According to an embodiment, the voltage level of the first node N1 may decrease from a value decreased and formed as much as the bias value during the precharge operation to the value enough to turn on the second PMOS transistor PT2.

Herein, the value enough to turn on the second PMOS transistor PT2 may be understood as a value which is smaller than or equal to a value obtained by subtracting the threshold voltage of the second PMOS transistor PT2 from the power supply voltage VDD.

According to an embodiment, as the voltage level of the first node N1 decreases, the second PMOS transistor PT2 may be turned on. Also, the voltage of the second node N2 may increase to the power supply voltage VDD based on the second PMOS transistor PT2 being turned on. For example, the voltage of the second node N2 may increase to the power supply voltage VDD in response to the second PMOS transistor PT2 being turned on.

According to an embodiment, in the read operation on the first memory cell MC11, the control logic circuit 130 may turn on the second switch SW2 by applying the inverse reset signal RSTN of the logic high level to the second switch SW2.

According to an embodiment, the first sense amplifier SA1 may output the voltage level of the second node N2 as the output signal DO through the output node ON. For example, in an example case in which the voltage level of the second node N2 increases to the power supply voltage VDD, the first sense amplifier SA1 may output a signal having a value “1”, through the output node ON.

Referring to the above components, according to an embodiment, the voltage level of the first node N1 may decrease during the precharge operation before the read operation on the first memory cell MC11.

According to an embodiment, during the precharge operation, the control logic circuit 130 may turn on the first switch SW1 such that the voltage level of the first node N1 decreases as much as the value determined depending on the characteristic difference of the second PMOS transistor PT2 and the fourth NMOS transistor NT4.

In addition, in the read operation on the first memory cell MC11, as the voltage level of the first node N1 additionally decreases from the value already decreased (or obtained) during the precharge operation, the second PMOS transistor PT2 may be turned on.

That is, as the control logic circuit 130 decreases the voltage level of the first node N1 as much as a value according to a characteristic of a transistor during the precharge operation, the control logic circuit 130 may reduce a time, which is taken to decrease the voltage level of the first node N1 to be smaller than or equal to a value for turning on the second PMOS transistor PT2, in the read operation.

Accordingly, the memory device 100 (or the first sense amplifier SA1) according to an embodiment of the present disclosure reduces a time taken to perform the read operation on a memory cell (e.g., the first memory cell MC11). For example,, the memory device 100 according to an embodiment of the present disclosure may improve a speed of the read operation on the memory cell (e.g., the first memory cell MC11).

According to an embodiment, due to a characteristic differences of a plurality of sense amplifiers included in the sense amplifier circuit 141, the memory device 100 may minimize a difference between times taken to perform the read operations on the plurality of memory cells MC11 to MCnm.

According to an embodiment, referring to the above components, the first PMOS transistor PT1 may be controlled by a ground voltage. In addition, the first NMOS transistor NT1 may be controlled by the power supply voltage VDD. Furthermore, the second NMOS transistor NT2 may be controlled by the voltage of the input node IN.

For example, the first sense amplifier SA1 according to an embodiment of the present disclosure may perform the read operation with a relatively small power, compared to the case where the first PMOS transistor PT1, the first NMOS transistor NT1, and the second NMOS transistor NT2 are respectively controlled by bias voltages generated through separate circuits.

Accordingly, the memory device 100 (or the first sense amplifier SA1) according to an embodiment of the present disclosure may reduce power consumption which is made during the read operation on the memory cell (e.g., the first memory cell MC11). That is, the memory device 100 according to an embodiment of the present disclosure may improve power efficiency of the read operation on the memory cell (e.g., the first memory cell MC11).

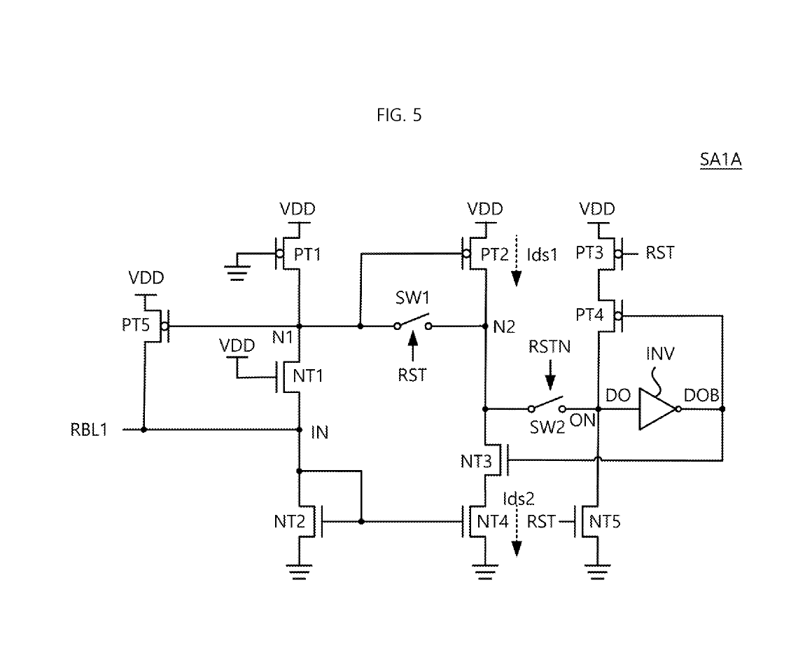

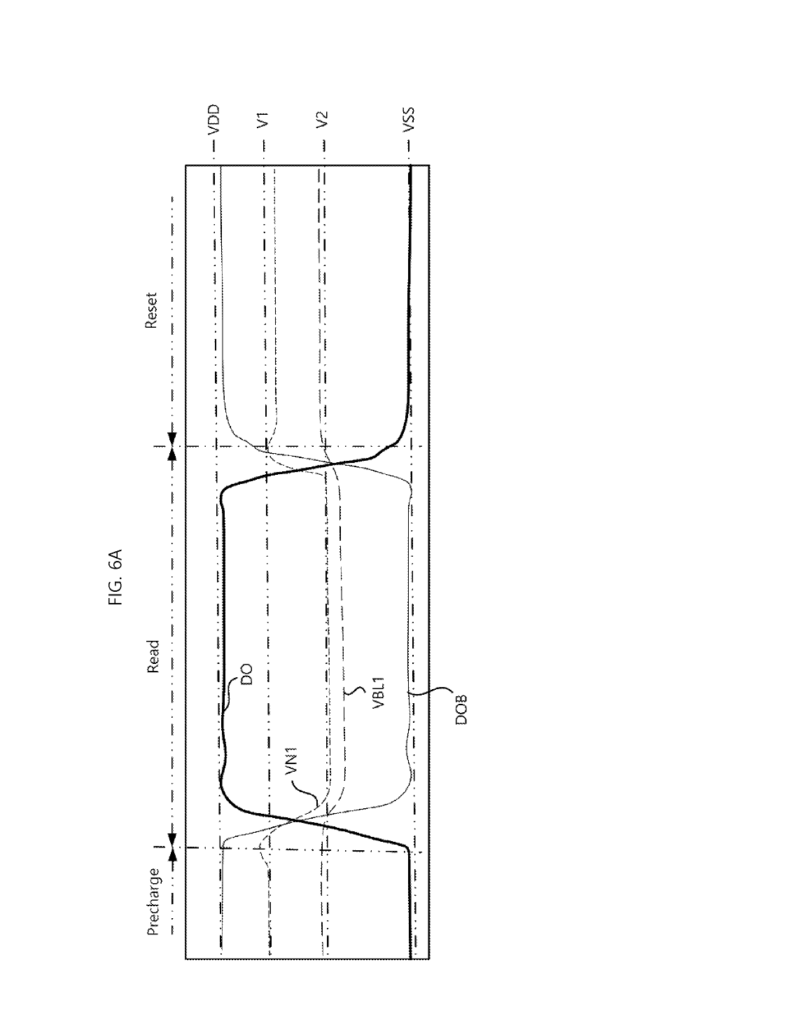

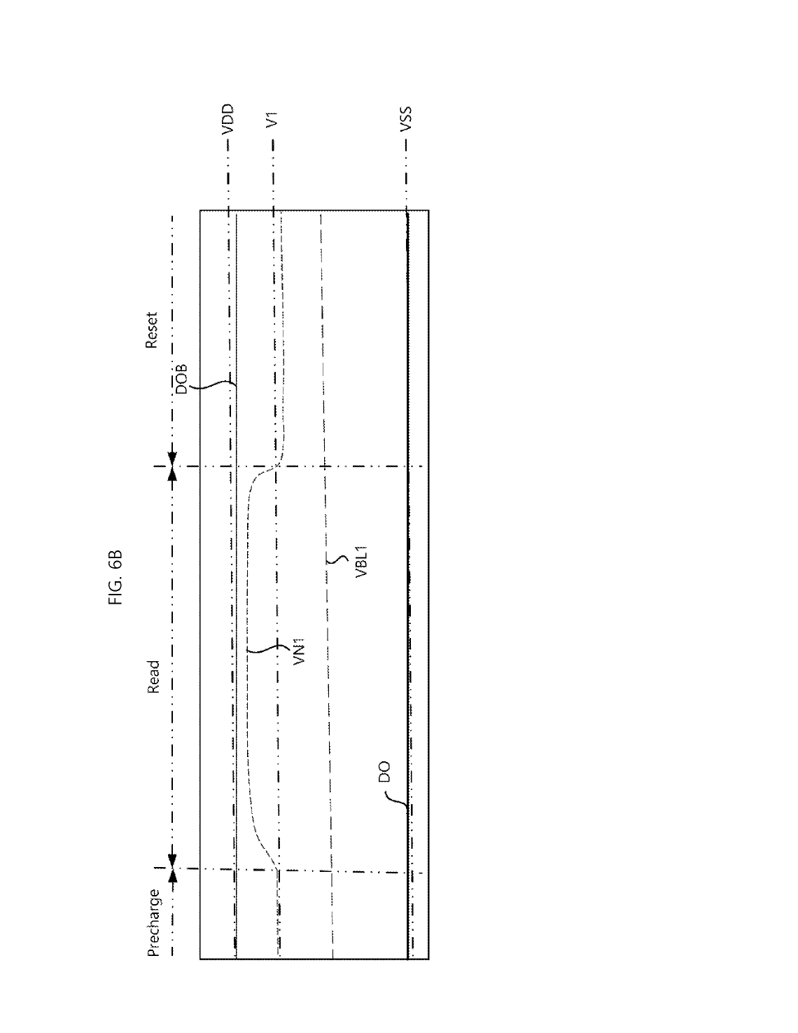

FIG. 5 is a circuit diagram of a first sense amplifier according to another embodiment. FIG. 6A illustrates voltages of respective nodes included in a first sense amplifier in an example operation in which data “1” stored in a first memory cell are read, according to an embodiment. FIG. 6B illustrates voltages of respective nodes included in a first sense amplifier in an example operation in which data “0” stored in a first memory cell are read, according to another embodiment.

Referring to FIG. 5, a first sense amplifier SA1A according to an embodiment may include a plurality of transistors PT1 to PT5 and NT1 to NT5, a first switch SW1, a second switch SW2, and an inverter INV. For example, the plurality of transistors may include a first PMOS transistor PT1, a second PMOS transistor PT2, a third PMOS transistor PT3, a fourth PMOS transistor PT4, a fifth PMOS transistor PT5, a first NMOS transistor NT1, a second NMOS transistor NT2, a third NMOS transistor NT3, a fourth NMOS transistor NT4, and a fifth NMOS transistor NT5.

Herein, the first sense amplifier SA1A illustrated in FIG. 5 may be referenced as further including the third PMOS transistor PT3, the fourth PMOS transistor PT4, the fifth PMOS transistor PT5, the fifth NMOS transistor NT5, and the inverter INV, from the configuration of the first sense amplifier SA1 illustrated in FIGS. 3A and 3B. Accordingly, components which are the same or substantially the same as the above components are marked by the same reference numerals/signs, and thus, additional description will be omitted to avoid redundancy.

According to an embodiment, the first sense amplifier SA1A may include the third PMOS transistor PT3, the fourth PMOS transistor PT4, the fifth NMOS transistor NT5 connected in series between the power supply voltage VDD and the ground.

Each of the third PMOS transistor PT3 and the fifth NMOS transistor NT5 may be turned on or turned off based on (or in response to) the reset signal RST received through the gate electrode of the respective transistor. Also, the fourth PMOS transistor PT4 may receive the inverse output signal DOB output from the inverter INV through the gate electrode thereof. Herein, the inverse output signal DOB may be understood as a signal obtained by inverting the output signal DO output through the output node ON by using the inverter INV.

According to an embodiment, the first sense amplifier SA1A may include the fifth PMOS transistor PT5 connected between the power supply voltage VDD and the first read bit line RBL1. The gate electrode of the fifth PMOS transistor PT5 may be connected to the first node N1.

Referring to FIGS. 5, 6A, and 6B together, the first sense amplifier SA1A according to an embodiment may read data stored in the first memory cell MC11.

According to an embodiment, the control logic circuit 130 may turn on the first switch SW1 in the precharge operation on the first memory cell MC11. In this case, the first node N1 and the second node N2 may be electrically connected.

According to an embodiment, in an example case in which the first node N1 and the second node N2 are connected, the voltage level of the first node N1 may decrease as much as a bias value which is determined depending on a characteristic of each of the second PMOS transistor PT2 and the fourth NMOS transistor NT4. Herein, a first node voltage VN1 may be referenced as a voltage of the first node N1.

According to an embodiment, while the first switch SW1 is turned on, the voltage level of the first node voltage VN1 may transition to a first voltage V1 as the first node N1 and the second node N2 are connected. Herein, the first voltage V1 may be understood as a value decreased from the power supply voltage VDD as much as the bias value determined depending on the characteristic of each of the second PMOS transistor PT2 and the fourth NMOS transistor NT4. For example, the first voltage V1 may change based on (or corresponding to) the characteristic of each of the second PMOS transistor PT2 and the fourth NMOS transistor NT4. For example, the first voltage V1 may decrease based on (or corresponding to) according to a bias amount based on the characteristic of each of the second PMOS transistor PT2 and the fourth NMOS transistor NT4.

Herein, the characteristic of each transistor may be understood as the magnitude of a drain current of each transistor under a specified condition. For example, the characteristic of the second PMOS transistor PT2 may include the magnitude of the first drain current Ids1 of the second PMOS transistor PT2. Also, the characteristic of the fourth NMOS transistor NT4 may include the magnitude of the second drain current Ids2 of the fourth NMOS transistor NT4.

Accordingly, while the first switch SW1 is turned on, the voltage level of the first node voltage VN1 may decrease as much as a bias value which is determined depending on a difference between the magnitude of the drain current Ids1 of the second PMOS transistor PT2 and the magnitude of the drain current Ids2 of the fourth NMOS transistor NT4.

Herein, for example, the bias value may be inversely proportional to the magnitude of the first drain current Ids1 and may be proportional to the magnitude of the second drain current Ids2. That is, as the magnitude of the first drain current Ids1 becomes smaller and the magnitude of the second drain current Ids2 becomes greater, the voltage level of the first node voltage VN1 may relatively decrease more. For another example, as the magnitude of the first drain current Ids1 becomes greater and the magnitude of the second drain current Ids2 becomes smaller, the voltage level of the first node voltage VN1 may relatively decrease less.

That is, during the precharge operation, the voltage level of the first node N1 may decrease from the power supply voltage VDD as much as a value according to a characteristic difference of the second PMOS transistor PT2 and the fourth NMOS transistor NT4.

According to an embodiment, the control logic circuit 130 may turn off the second switch SW2 in the precharge operation. In this case, the second node N2 may be electrically separated from the output node ON.

For example, the control logic circuit 130 may open the second switch SW2 to prevent a voltage change of the first node N1 and the second node N2 according to the precharge operation from affecting the output node ON.

According to an embodiment, the control logic circuit 130 may turn off the first switch SW1 in the read operation on the first memory cell MC11. In this case, the first node N1 and the second node N2 may be electrically separated from each other.

Referring to FIGS. 2, 4, 5, and 6A together, according to an embodiment, assuming that a value of data stored in the first memory cell MC11 is “1”, as the first read signal RS1 is applied to the first memory cell MC11 through the first read word line RWL1, the voltage level of the first node voltage VN1 may decrease.

According to an embodiment, assuming that data “1” are previously stored in the first memory cell MC11, the first read transistor RT1 and the second read transistor RT2 of the first memory cell MC11 may be turned on based on the first read signal RS1 applied through the first read word line RWL1. For example, the first read transistor RT1 and the second read transistor RT2 of the first memory cell MC11 may be turned on in response to the first read signal RS1 applied through the first read word line RWL1.

As the first read transistor RT1 and the second read transistor RT2 are turned on, the first node N1 may be connected to the ground through the first read bit line RBL1. That is, in the read operation on the first memory cell MC11, a current may flow from the first node N1 to the ground through the first read bit line RBL1.

Herein, referring to FIG. 6A, the first node voltage VN1 may decrease from the first voltage V1 to a second voltage V2 to turn on the second PMOS transistor PT2.

According to an embodiment, the voltage level of the first node voltage VN1 may decrease to the second voltage V2 from the first voltage V1 decreased from the power supply voltage VDD as much as the bias value during the precharge operation.

Herein, the second voltage V2 may be understood as a value which is smaller than or equal to a value obtained by subtracting the threshold voltage of the second PMOS transistor PT2 from the power supply voltage VDD.

Referring to FIG. 5, as the voltage level of the first node voltage VN1 decreases, the second PMOS transistor PT2 may be turned on. Also, the voltage of the second node N2 may increase to the power supply voltage VDD based on the second PMOS transistor PT2 being turned on. For example, the voltage of the second node N2 may increase to the power supply voltage VDD in response to the second PMOS transistor PT2 being turned on.

According to an embodiment, in the read operation on the first memory cell MC11, the control logic circuit 130 may turn on the second switch SW2 by applying the inverse reset signal RSTN of the logic high level to the second switch SW2.

According to the above description, the first sense amplifier SA1A may output the output signal DO having a value “1” through the output node ON. Also, the inverter INV may output the inverse output signal DOB having a value of “0” by inverting the output signal DO.

In an embodiment, in a reset operation, when the reset signal RST of the logic high level is applied, the third PMOS transistor PT3 may be turned off, and the fifth NMOS transistor NT5 may be turned on.

Accordingly, the voltage level of the output node ON may transition to a ground voltage VSS. For example, after the read operation on the first memory cell MC11, the voltage level of the output signal DO output through the output node ON may transition to the ground voltage VSS based on (or in response to) the reset signal RST of the logic high level.

Herein, for example, the reset operation may be referenced as an operation substantially the same as the precharge operation performed before the read operation.

Referring to FIGS. 5 and 6B together, according to an embodiment, assuming that a value of data stored in the first memory cell MC11 is “0”, as the first switch SW1 is turned off, the voltage level of the first node voltage VN1 may increase.

According to an embodiment, in the read operation on the first memory cell MC11, based on (or in response to) the first switch SW1 being turned off, the first node N1 and the second node N2 may be electrically separated from each other.

According to an embodiment, referring to FIG. 2, in an example case in which a value of data stored in the first memory cell MC11 is “0”, the second read transistor RT2 of the first memory cell MC11 may be turned off. That is, one end of the first read bit line RBL1 may be open.

That is, in the read operation on the first memory cell MC11, a current may flow from the power supply voltage VDD to the ground through the first PMOS transistor PT1, the first NMOS transistor NT1, and the second NMOS transistor NT2.

Accordingly, in the read operation on the first memory cell MC11, the voltage level of the first node voltage VN1 may increase to the power supply voltage VDD.

According to an embodiment, referring to FIG. 5, as the voltage level of the first node voltage VN1 increases, the second PMOS transistor PT2 may be turned off.

According to an embodiment, through the precharge operation, the inverse output signal DOB having a value “1” may be output. Accordingly, the third NMOS transistor NT3 may be turned on based on (or in response to) the inverse output signal DOB having a value “1”.

In addition, the fourth NMOS transistor NT4 may be turned on response on a voltage VBL1 of the first read bit line RBL1.

Accordingly, the second node N2 may be connected to the ground through the third NMOS transistor NT3 and the fourth NMOS transistor NT4. That is, in the read operation on the first memory cell MC11, the voltage level of the second node N2 may decrease to the ground voltage VSS.

According to an embodiment, the control logic circuit 130 may turn on the second switch SW2 in the read operation on the first memory cell MC11.

According to the above description, the first sense amplifier SA1A may output the output signal DO having a value “0”, through the output node ON. Also, the inverter INV may output the inverse output signal DOB having a value “1”, by inverting the output signal DO.

Referring to the above components, according to an embodiment, the voltage level of the first node N1 may decrease during the precharge operation before the read operation on the first memory cell MC11.

According to an embodiment, during the precharge operation, the control logic circuit 130 may turn on the first switch SW1 to connect the first node N1 and the second node N2. In other words, the control logic circuit 130 may decrease the voltage level of the first node voltage VN1 as much as the value determined depending on the characteristic difference of the second PMOS transistor PT2 and the fourth NMOS transistor NT4.

In addition, in the read operation on the first memory cell MC11, as the voltage level of the first node voltage VN1 additionally decreases from the value decreased and formed during the precharge operation, the second PMOS transistor PT2 may be turned on. For example, in the read operation on the first memory cell MC11, the voltage level of the first node voltage VN1 may transition from the first voltage V1 to the second voltage V2 enough to turn on the second PMOS transistor PT2.

As the control logic circuit 130 decreases the voltage level of the first node N1 as much as a value according to a characteristic of a transistor during the precharge operation, the control logic circuit 130 may reduce a time, which is taken to decrease the voltage level of the first node N1 to be smaller than or equal to a value for turning on the second PMOS transistor PT2, in the read operation.

That is, the control logic circuit 130 may minimize a time which increases due to a characteristic of a transistor in the read operation.

Accordingly, the memory device 100 (or the first sense amplifier SA1A) according to an embodiment of the present disclosure reduces a time taken to perform the read operation on a memory cell (e.g., the first memory cell MC11).

According to an embodiment, referring to the above components, the first PMOS transistor PT1 may be controlled by the ground voltage. In addition, the first NMOS transistor NT1 may be controlled by the power supply voltage VDD. Furthermore, the second NMOS transistor NT2 may be controlled by the voltage of the input node IN.

That is, the first sense amplifier SA1A according to an embodiment of the present disclosure may perform the read operation with a relatively small power, compared to the case where the first PMOS transistor PT1, the first NMOS transistor NT1, and the second NMOS transistor NT2 are respectively controlled by bias voltages generated through separate circuits.

Accordingly, the memory device 100 (or the first sense amplifier SA1A) according to an embodiment of the present disclosure may reduce power consumption which is made during the read operation on the memory cell (e.g., the first memory cell MC11).

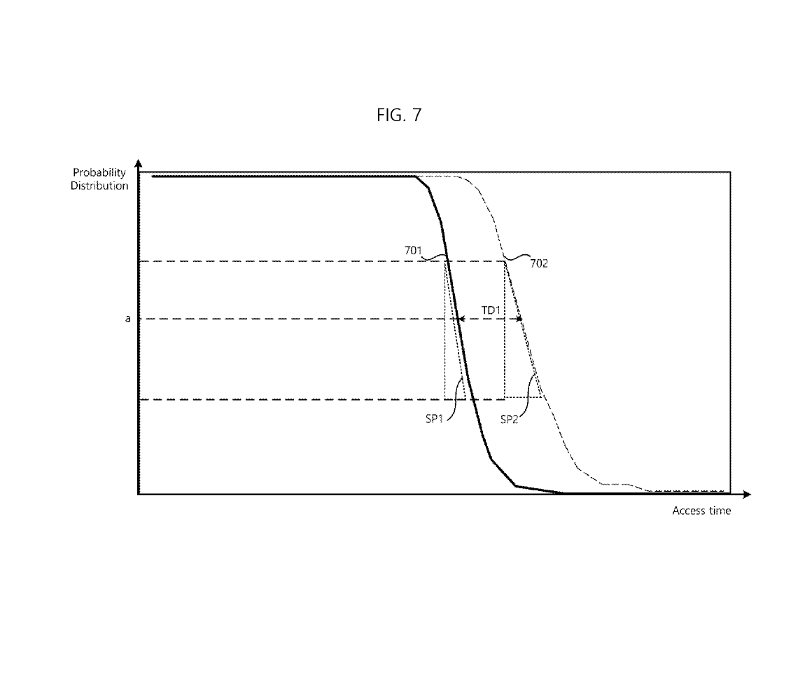

FIG. 7 illustrates a cumulative probability distribution function of an access time using a first sense amplifier according to an embodiment and a cumulative probability distribution function of an access time using a sense amplifier not including a first switch and a second switch.

Referring to FIG. 7, in an example case of reading data stored in the first memory cell MC11 by using the first sense amplifier SA1 according to an embodiment, the access time to a memory cell may decrease.

Herein, the first sense amplifier SA1 may be understood as being substantially the same as the first sense amplifier SA1 illustrated in FIGS. 3A and 3B.

Accordingly, during the precharge operation, the control logic circuit 130 according to an embodiment may turn on the first switch SW1 to connect the first node N1 and the second node N2. In other words, the control logic circuit 130 may decrease the voltage level of the first node voltage VN1 as much as the value determined depending on the characteristic difference of the second PMOS transistor PT2 and the fourth NMOS transistor NT4.

In addition, in the read operation on the first memory cell MC11, as the voltage level of the first node voltage VN1 additionally decreases from the value decreased and formed during the precharge operation, the second PMOS transistor PT2 may be turned on. For example, in the read operation on the first memory cell MC11, the voltage level of the first node voltage VN1 may transition from the first voltage V1 to the second voltage V2 enough to turn on the second PMOS transistor PT2.

For example, as the control logic circuit 130 decreases the voltage level of the first node N1 as much as a value according to a characteristic of a transistor during the precharge operation, the control logic circuit 130 may reduce a time, which is taken to decrease the voltage level of the first node N1 to be smaller than or equal to a value for turning on the second PMOS transistor PT2, in the read operation.

Accordingly, the memory device 100 may have a relatively short access time, compared to the case of reading data stored in the first memory cell MC11 by using a sense amplifier not including the first switch SW1 and the second switch SW2.

Referring to FIG. 7, a first cumulative probability distribution function 701 shows a probability distribution of an access time corresponding to a case in which the read operation on the first memory cell MC11 is performed by using the first sense amplifier SA1 according to an embodiment of the present disclosure. According to an embodiment, in FIG. 7, a second cumulative probability distribution function 702 shows a probability distribution of an access time corresponding to in a case in which the read operation on the first memory cell MC11 is performed by using a sense amplifier not including the first switch SW1 and the second switch SW2 (for example, as illustrated in FIGS. 3A and 3B).

For example, in a specified probability distribution “a”, the first cumulative probability distribution function 701 according to an embodiment of the present disclosure may have the access time smaller than the second cumulative probability distribution function 702, as much as a first time difference TD1.

For example, the memory device 100 according to an embodiment of the present disclosure may reduce a time necessary for a memory cell (e.g., a time taken to perform a core operation (e.g., a read operation) on the first memory cell MC11).

According to an embodiment, the first cumulative probability distribution function 701 may have a relatively sharp slope, compared to the second cumulative probability distribution function 702. For example, the first cumulative probability distribution function 701 may have a first slope SP1, and the second cumulative probability distribution function 702 may have a second slope SP2 smaller than the first slope SP1.

That is, in the case of performing the read operation on the first memory cell MC11 by using the first sense amplifier SA1 according to an embodiment of the present disclosure, the memory device 100 may decrease a deviation of the access time due to a characteristic difference of internal transistors.

According to the above description, the memory device 100 according to an embodiment of the present disclosure may minimize the following issue due to characteristic differences of a plurality of sense amplifiers included in the sense amplifier circuit 141: a difference between times taken to perform the read operations on the plurality of memory cells MC11 to MCnm.

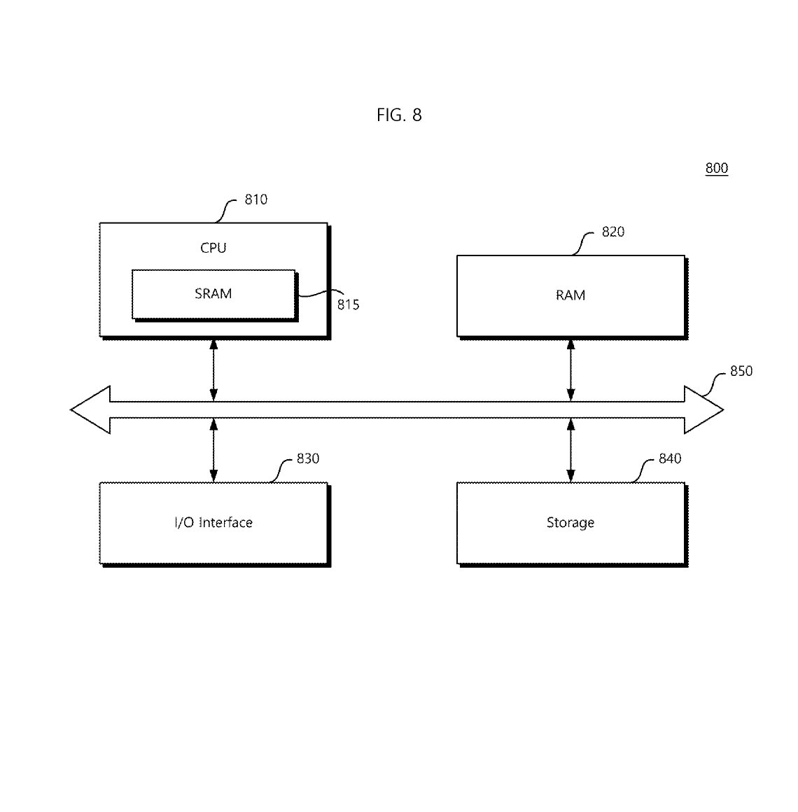

FIG. 8 is a block diagram illustrating an example of a hardware structure of a mobile device including a memory device according to an embodiment of the present disclosure.

Referring to FIG. 8, a mobile device 800 may include a central processing unit (CPU) 810, a RAM 820, an input/output (I/O) interface 830, storage 840, and a system bus 850. Herein, the mobile device 800 may be a computer system or a workstation.

The CPU 810 may execute software which is to be performed by the mobile device 800. For example, the software may include, but is not limited to, an application program, an operating system, and device drivers. The CPU 810 may execute an operating system (OS) loaded to the RAM 820. The CPU 810 may execute various application programs which are to be driven based on the operating system (OS).

In an embodiment, the CPU 810 may include an SRAM 815. Herein, the SRAM 815 may be understood as an example of the memory device 100 illustrated in FIG. 1.

Accordingly, the SRAM 815 according to an embodiment may include the first sense amplifier SA1 as illustrated, for example in FIGS. 3A and 3B. The first sense amplifier SA1 may include a plurality of transistors controlled by (or operated based on) the power supply voltage VDD, the ground voltage VSS, and a voltage of a read bit line. According to an embodiment, the SRAM 815 may include the control logic circuit 130 which controls the first sense amplifier SA1.

The first sense amplifier SA1 according to an embodiment may decrease the voltage level of the first node N1 in the first sense amplifier SA1 during the precharge operation before the read operation on the first memory cell MC11.

For example, as the control logic circuit 130 decreases the voltage level of the first node N1 as much as a value according to a characteristic of a transistor during the precharge operation, the control logic circuit 130 may reduce a time, which is taken to decrease the voltage level of the first node N1 to be smaller than or equal to a value for turning on the second PMOS transistor PT2, in the read operation.

Accordingly, the SRAM 815 according to an embodiment of the present disclosure may reduce a time taken to perform the read operation on the memory cell (e.g., the first memory cell MC11). That is, the SRAM 815 according to an embodiment of the present disclosure may improve a speed of the read operation on the memory cell (e.g., the first memory cell MC11).

The operating system (OS) or the application programs may be loaded to the RAM 820. When the mobile device 800 is booted up, an OS image stored in the storage 840 may be loaded to the RAM 820 depending on a booting sequence. All input/output operations of the mobile device 800 may be supported by the operating system (OS). Likewise, the application programs which are selected by the user or are for providing a basic service may be loaded to the RAM 820. The RAM 820 may be a volatile memory such as a static random access memory (SRAM) or a dynamic random access memory (DRAM) or a nonvolatile memory such as a PRAM, an MRAM, an ReRAM, an FRAM, or a NOR flash memory.

The input/output interface 830 may control the user input and output from user interface devices. For example, the input/output interface 830 may include a keyboard, a touch pad, or a monitor and may be provided with a command or data from the user.

Herein, the input/output interface 830 may be connected to the input/output driver 140 of the memory device 100 of FIG. 1. That is, for example, the input/output interface 830 may output the data provided from the input/output driver 140 or may store the data received from the outside in the memory cell array 111 through the input/output driver 140.

The storage 840 is provided as a storage medium of the mobile device 800. The storage 840 may be provided as a memory card (e.g., an MMC, an eMMC, an SD card, or a microSD card) or a hard disk drive (HDD). The storage 840 may include a NAND-type flash memory having a high-capacity storage capability. Alternatively, the storage 840 may include a next-generation nonvolatile memory such as a PRAM, an MRAM, an ReRAM, or an FRAM.

The system bus 850 may be understood as a system bus for providing a network within the mobile device 800. The CPU 810, the RAM 820, the input/output interface 830, and the storage 840 may be connected through the system bus 850 to exchange data with each other. However, the configuration of the system bus 850 is not limited to the above description and may further include arbitration means for efficient management.

Referring to the above components, the mobile device 800 may include the SRAM 815 which includes a sense amplifier including transistors controlled by the power supply voltage VDD, the ground voltage VSS, and a read bit line voltage.

Accordingly, the mobile device 800 may reduce power consumption while operating in a mobile environment.

According to an embodiment, as the mobile device 800 decreases the voltage level of the first node N1 as much as a value according to a characteristic of a transistor during the precharge operation in association with the sense amplifier of the SRAM 815, the mobile device 800 may reduce a time taken to decrease the voltage level of the first node N1 to be smaller than or equal to a value for turning on the second PMOS transistor PT2, in the read operation.

As such, the mobile device 800 according to an embodiment of the present disclosure may reduce a time taken to perform the read operation on the memory cell.

As described above, the first sense amplifier SA1 according to an embodiment of the present disclosure may decrease the voltage level of the first node N1 in the first sense amplifier SA1 during the precharge operation before the read operation on the first memory cell MC11.

According to an embodiment, during the precharge operation, the control logic circuit 130 may turn on the first switch SW1 to connect the first node N1 and the second node N2. In other words, the control logic circuit 130 may decrease the voltage level of the first node voltage VN1 as much as the value determined depending on the characteristic difference of the second PMOS transistor PT2 and the fourth NMOS transistor NT4.

In addition, in the read operation on the first memory cell MC11, as the voltage level of the first node voltage VN1 additionally decreases from the value decreased and formed during the precharge operation, the second PMOS transistor PT2 may be turned on. For example, in the read operation on the first memory cell MC11, the voltage level of the first node voltage VN1 may transition from the first voltage V1 to the second voltage V2 enough to turn on the second PMOS transistor PT2.

As the control logic circuit 130 decreases the voltage level of the first node N1 as much as a value according to a characteristic of a transistor during the precharge operation, the control logic circuit 130 may reduce a time, which is taken to decrease the voltage level of the first node N1 to be smaller than or equal to a value for turning on the second PMOS transistor PT2, in the read operation.

For example, the control logic circuit 130 may minimize a time which increases due to a characteristic of a transistor in the read operation.

Accordingly, the memory device 100 (or the first sense amplifier SA1) according to an embodiment of the present disclosure reduces a time taken to perform the read operation on a memory cell (e.g., the first memory cell MC11). That is, the memory device 100 according to an embodiment of the present disclosure may improve a speed of the read operation on the memory cell (e.g., the first memory cell MC11).

According to an embodiment, the memory device 100 may minimize the following issue due to characteristic differences of a plurality of sense amplifiers included in the sense amplifier circuit 141: a difference between times taken to perform the read operations on the plurality of memory cells MC11 to MCnm.

According to an embodiment, referring to the above components, the first PMOS transistor PT1 may be controlled by the ground voltage. In addition, the first NMOS transistor NT1 may be controlled by the power supply voltage VDD. Furthermore, the second NMOS transistor NT2 may be controlled by the voltage of the input node IN.

That is, the first sense amplifier SA1 according to an embodiment of the present disclosure may perform the read operation with a relatively small power, compared to the case where the first PMOS transistor PT1, the first NMOS transistor NT1, and the second NMOS transistor NT2 are respectively controlled by bias voltages generated through separate circuits.

Accordingly, the memory device 100 (or the first sense amplifier SA1) according to an embodiment of the present disclosure may reduce power consumption which is made during the read operation on the memory cell (e.g., the first memory cell MC11). That is, the memory device 100 according to an embodiment of the present disclosure may improve power efficiency of the read operation on the memory cell (e.g., the first memory cell MC11).

A sense amplifier according to an embodiment of the present disclosure may improve a speed and power efficiency of a read operation on a memory cell.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A sense amplifier comprising:
a first p-channel metal–oxide–semiconductor (PMOS) transistor and a first n-channel metal–oxide–semiconductor (NMOS) transistor connected in series between a power supply voltage and an input node of the sense amplifier;
a second NMOS transistor connected between the input node and a ground;
a second PMOS transistor, a third NMOS transistor, and a fourth NMOS transistor connected in series between the power supply voltage and the ground;
a first switch connected between a first node between the first PMOS transistor and the first NMOS transistor and a second node between the second PMOS transistor and the third NMOS transistor; and
a second switch connected between the second node and an output node of the sense amplifier,
wherein a gate electrode of the first PMOS transistor is connected to the ground,
wherein a gate electrode of the first NMOS transistor is connected to the power supply voltage,
wherein a gate electrode of the second NMOS transistor is connected to the input node, and
wherein a gate electrode of the second PMOS transistor is connected to the first node.

2. The sense amplifier of claim 1, wherein the first switch is turned on based on a reset signal, and
wherein the second switch is turned on based on an inverse reset signal, which is an inverted version of the reset signal.

3. The sense amplifier of claim 2, wherein, while the first switch is turned on, the first node and the second node are connected and a voltage of the first node changes from the power supply voltage to a first voltage based on a characteristic of each of the second PMOS transistor and the fourth NMOS transistor.

4. The sense amplifier of claim 3, wherein the characteristic of the second PMOS transistor comprises a magnitude of a first drain current of the second PMOS transistor,
wherein the characteristic of the fourth NMOS transistor comprises a magnitude of a second drain current of the fourth NMOS transistor, and
wherein the voltage of the first node changes from the power supply voltage to the first voltage by a bias value, which is inversely proportional to the magnitude of the first drain current and is proportional to the magnitude of the second drain current.

5. The sense amplifier of claim 3, wherein, while the first switch is turned off, the first node is connected to the ground through a read bit line connected to a memory cell of a memory device, and the voltage of the first node changes from the first voltage to a second voltage, and
wherein, based on the voltage of the first node changing to the second voltage, the second PMOS transistor is turned on, and a voltage of the second node and the output node changes to the power supply voltage.

6. The sense amplifier of claim 2, wherein a gate electrode of the fourth NMOS transistor is connected to the gate electrode of the second NMOS transistor and a read bit line connected to a memory cell of a memory device.

7. The sense amplifier of claim 2, further comprising:
an inverter configured to invert an output signal output from the output node; and
a third PMOS transistor, a fourth PMOS transistor, and a fifth NMOS transistor connected in series between the power supply voltage and the ground,
wherein each of the third PMOS transistor and the fifth NMOS transistor is configured to receive the reset signal through a gate electrode of the respective transistor, and
wherein the fourth PMOS transistor is configured to receive an inverse output signal output from the inverter through a gate electrode of the fourth PMOS transistor.

8. The sense amplifier of claim 7, wherein, as the third PMOS transistor is turned off based on the reset signal and the fifth NMOS transistor is turned on based on the reset signal, a voltage of the output node changes to a ground voltage.

9. The sense amplifier of claim 7, wherein the third NMOS transistor is configured to receive the inverse output signal output from the inverter through a gate electrode third NMOS transistor.

10. The sense amplifier of claim 7, further comprising:
a fifth PMOS transistor connected between the power supply voltage and a read bit line connected to a memory cell of a memory device and comprising a gate electrode connected to the first node.

11. A memory device comprising:
a memory cell array comprising a plurality of memory cells connected to a first read bit line; and
a sense amplifier connected to the first read bit line,
wherein the sense amplifier comprises:
a first p-channel metal–oxide–semiconductor (PMOS) transistor, a first n-channel metal–oxide–semiconductor (NMOS) transistor, and a second NMOS transistor connected in series between a power supply voltage and a ground;
a second PMOS transistor, a third NMOS transistor, and a fourth NMOS transistor connected in series between the power supply voltage and the ground; and
a first switch connected between a first node between the first PMOS transistor and the first NMOS transistor and a second node between the second PMOS transistor and the third NMOS transistor,
wherein a gate electrode of the first PMOS transistor is connected to the ground,
wherein a gate electrode of the first NMOS transistor is connected to the power supply voltage, and
wherein a gate electrode of the second PMOS transistor is connected to the first node.

12. The memory device of claim 11, further comprising:
a control logic circuit connected to the sense amplifier,
wherein the control logic circuit is configured to output a reset signal to turn on the first switch, and
wherein, while the first switch is turned on, the first node and the second node are connected and a voltage of the first node changes from the power supply voltage to a first voltage based on a characteristic of each of the second PMOS transistor and the fourth NMOS transistor.

13. The memory device of claim 12, further comprising:
a second switch connected between the second node and an output node of the sense amplifier,
wherein, while the control logic circuit outputs the reset signal , the control logic circuit is further configured to output an inverse reset signal to turn off the second switch, and wherein the inverse reset signal is an inverted version of the reset signal to the second switch.

14. The memory device of claim 12, wherein the characteristic of the second PMOS transistor comprises a magnitude of a first drain current of the second PMOS transistor,
wherein the characteristic of the fourth NMOS transistor comprises a magnitude of a second drain current of the fourth NMOS transistor, and
wherein the voltage of the first node changes from the power supply voltage to the first voltage by a bias value, which is inversely proportional to the magnitude of the first drain current and is proportional to the magnitude of the second drain current.

15. The memory device of claim 13, wherein, in a read operation on a first memory cell connected to the first read bit line, the control logic circuit is further configured to:
turn off the first switch and turn on the second switch; and
determine data stored in the first memory cell, based on an output signal output from the output node connected to the second node.

16. The memory device of claim 15, wherein, while the first switch is turned off and the second switch is turned on, the voltage of the first node changes from the first voltage to a second voltage,
wherein the second PMOS transistor is turned on based on the voltage of the first node changing to the second voltage, and
wherein a voltage of the second node changes to the power supply voltage based on the second PMOS transistor being turned on.

17. The memory device of claim 11, wherein the sense amplifier is connected to the first read bit line through an input node of the sense amplifier between the first NMOS transistor and the second NMOS transistor, and
wherein a gate electrode of the second NMOS transistor is connected to the input node.

18. A sense amplifier which is connected to a plurality of memory cells, comprising:
a first p-channel metal–oxide–semiconductor (PMOS) transistor, a first n-channel metal–oxide–semiconductor (NMOS) transistor, and a second NMOS transistor connected in series between a power supply voltage and a ground;
a first switch connected between a first node between the first PMOS transistor and the first NMOS transistor and a second node;
a second PMOS transistor connected between the power supply voltage and the second node; and
a second switch connected between the second node and an output node,
wherein the first switch is turned on based on a reset signal, and
wherein, while the first switch is turned on, the first node and the second node are connected and a voltage of the first node changes from the power supply voltage to a first voltage based on a characteristic of the second PMOS transistor.

19. The sense amplifier of claim 18, wherein, while the first switch is turned off, the voltage of the first node changes from the first voltage to a second voltage, and
wherein, based on the voltage of the first node changing to the second voltage, the second PMOS transistor is turned on, and a voltage of the second node and the output node changes to the power supply voltage.

20. The sense amplifier of claim 18, wherein a gate electrode of the first PMOS transistor is connected to the ground,
wherein a gate electrode of the first NMOS transistor is connected to the power supply voltage,
wherein a gate electrode of the second NMOS transistor is connected to one node between the first NMOS transistor and the second NMOS transistor, and
wherein a gate electrode of the second PMOS transistor is connected to the first node.
